(19) United States
(12) Patent Application Publication
(10) Pub. No.: US 2002/0141003 A1
(43) Pub. Date: Oct. 3, 2002

(54) Method of three dimensional color vector determinant for automatic kanji and chinese character detection and enhancement

(75) Inventors: William Ho Chang, Vancouver, WA (US); Makoto Otsu, Yamato Koriyama-shi (JP)

Correspondence Address: Robert D. Varitz, ROBERT D. VARITZ, P.C., 380 Harrison Square, 1800 S.W. First Avenue, Portland, OR, 97201, US

(73) Assignee: Sharp Laboratories of America, Inc.

(21) Appl. No.: 09/761,441

(22) Filed: Jan. 16, 2001

(51) Int. Cl. G03F 3/08

(52) U.S. Cl. 358/518; 358/520

(57) ABSTRACT

A method for correcting misregistration of scanned thin line character components includes detecting a misregistered pixel; determining whether the misregistered pixel is part of a character; applying a three-dimensional color vector determinant to the misregistered pixel, and reducing the chrominance component of the misregistered pixel to provide a corrected pixel.

### RELATED APPLICATION

This application is related to U.S. patent application Ser. No. 09/419,602, filed Oct. 18, 1999, for Least squares method for color misregistration detection and correction in image data, of the inventors named herein and assigned to the same entity.

### FIELD OF THE INVENTION

This invention relates to the field of digital image processing and more particularly to a vector based method of automatic color misregistration removal and enhancement, for characters having thin line components therein, such as Kanji and Chinese characters, caused by CCD based images and other scanning devices.

### BACKGROUND OF THE INVENTION

Color scanners operate by capturing an image, from an input color image document, consisting of primary color component signals, such as red, green, and blue (RGB), from a set of charge-coupled devices (CCDs), which move relative to the input color image and which are placed a distance apart from one another in the slow scan (Y) sub-direction Depending on the scanner and the technology used, images capture may require three passes of the CCD array, or may require only one pass, i.e., the image may be captured in three separate exposures or in one exposure. Regardless of the number of passes or exposures, there is always misalignments in the CCD array, and hence, in the resultant RGB signal.

The misalignment in the RGB signal is caused by faulty superposition or color misregistration producing an undesirable color fringing on the edges of text, graphics, and drawings. Color fringes often appear as cyan artifacts, caused by misregistration of the red signal, or magenta artifacts, caused by misregistration of the green signal. Color misregistration of the blue signal is generally not as perceptible by the human visual system (HVS), because of the HVS low bandwidth and sensitivity for visual systems in spatial frequency generated by low contrast sensitivity functions in the blue portion of the visible color spectrum.

Color signal misalignment is often severe in the slow sub-scanning Y direction. Vibration, scanning motion, and the mechanical and optical design of the scanner are all factors leading to color misregistration or faulty superposition of the three primary colors. For example, in a three exposure scanner, Y misalignments are caused by the quality of the optics used as well as the uniformity inconsistency of the scanner's optical carriage motion. Some prior art attempts to detect color misregistration and correct them through mechanical means are described in U.S. Pat. No. 5,737,003, while an optical means to correct the problem is described in U.S. Pat. No. 4,583,016. Other techniques involve storing predetermined patterns to detect color registration in an imaging circuitry, as discussed in U.S. Pat. Nos. 5,774,156 and 5,760,815 However, most of these prior art techniques are either too expensive to implement in a low-cost imaging product, or have an inaccuracy rate which is too high to provide a substantial benefit.

The use of color scanning for drawings and text documents has increased dramatically. This is driven by lower-cost in color copying, color document scanning, digital photography, color fax, and color printing. To maintain an adequate profit margin and competitiveness, there needs a color misregistration solution which is low-cost, fast, and has a high accuracy for automatically solving color registration problems for image capturing and outputting devices.

Automatic color misregistration removal methods exist for Roman characters. Unfortunately, no automatic solution exist in the known prior art which is intended specifically to solve or enhance misregistration problems with Kanji characters. There is a large market for digital imaging products in Asia, including China, Japan, and Southeast Asia. Kanji or Chinese characters are very important and cannot be ignored if digital imaging products are to be successful in Asia. The difficulty in scanning Kanji characters is that the characters include lines ranging between very broad to very thin. The problem of color misregistration is exacerbated by the very thin portions of these characters. Other alphabets having a combination of very thick and thin lines include Arabic, Hebrew, Greek, and Cryllic, and share this problem.

There are non-Kanji specific proposals to solve color misregistration problem in the known prior art. These general image processing techniques described in prior art to detect color misregistration includes subjective heuristic U.S. Pat. No. 4,583,1 16, approximation, U.S. Pat. No 5,500,746, and truncation techniques U.S. Pat. No. 5,907,414. Known prior art techniques generally rely on empirical data to identify color misregistration. The present invention, using 3D color determinant mathematics, is more objective, repeatable, and customizable into a variety of imaging products.

Color misregistration detection and correction in the prior art is not an accurate process. For example, in U.S. Pat. No. 5,477,35, color misregistration error is found by performing edge detection inside a 5×5 window. In addition, a variety of text structure patterns are compared with image pixels to determine whether the pixel is located at an edge of text. If an edge pattern is detected the color of that pixel is changed to black pixel. This method may work in Roman characters but does not work in thin line character components, as found in Kanji. Kanji Thin line character components cannot be detected using predetermined patterns. Another similar technique is described in U.S. Pat. No. 4,953,013, which detects the edge of a black text. Yet, still another detection and correction algorithm is found in U.S. Pat. No. 5,764,388, where a CMY color of a pixel is analyzed, and if the chrominance is less than that of a predetermined threshold, the chrominance is set to zero to eliminate the suspected color misregistration error. Relying solely on chrominance values is not sufficient for detecting color misregistration in thin line character components.

U.S. Pat. No. 4,583, 116, granted Apr. 15, 1986, to Henning et al., for Method and apparatus for eliminating the effects in images polychromatic printing due to faulty registration of superimposed printing of color separation, describes a method and apparatus for eliminating image effects in poly-chromatic printing which arise because of misregistration in the superimposed printing of individual color separations signals, CMYK. This technique requires finding the contour for each individual plane. A color registration error is found between the two darkest contours A weighting factor of 0.3 for yellow, 0.7 for magenta, 0.9 for cyan, and 0 2 for black, is used to determine the two darkest contours.

U.S. Pat. No. 4,733,296, granted Mar. 22, 1988, to Honbo et al., for Multi-tube color TV camera in which linear and nonlinear components of the registration error due to chromatic aberration of a lens are corrected with corresponding deflection correction signals, describes a technique for correcting misregistration error caused by chromatic operations in optical devices, such as zoom lenses, dichromic prism, etc. This technique provides an arrangement in which the chromatic aberration of events is separated into a linear component of a magnitude in proportion to the distance H from the optical center, namely, the optical axis into the other non-linear component, and two individual correction waveform corresponding to each of these components are generated. Registration error is corrected by this generated waveform.

U.S. Pat. No. 4,953,013, granted Aug. 28, 1990, to Tsuji et al., for Color image processing device, describes a method of printing black text where the color fringing is minimized due to CMY Ink balance and alignment. In this patent, the main objectives are to detect the edge of a black character. A variety of edge detection patterns are determined for use in detecting black text.

U.S. Pat. No. 5,477,35, granted Dec. 19, 1995 to Tai, for Method and apparatus of copying of black text on documents using a color scanner, describes a method of detecting misregistration through edge detection and black text detection. A processing pixel is distinguished inside a 5×5 window; edge detection is performed by identify text structure, a black text is identified by finding a neighboring white pixel in the window for background and a high contrast pixel for the current pixel. With the identified high contrast edge area of a black text found, a black color will be output for that pixel with a LAB (100, 0,0).

U.S. Pat. No. 5,500,746, granted Mar. 19, 1996, to Aida, for Color image input apparatus, describes a technique for correcting color misregistration for digital cameras and scanners in the main scanning direction. Color is shifted plus or minus one dot by averaging or interpolating the difference in the main scanning direction, with correlation coefficients

U.S. Pat. No. 5,555,107, granted Sep. 10,1996, to Funada et al., for Image processing apparatus for judging a color using spatial frequency corrected color component signals, describes a system wherein various color components are processed according to their spatial frequency gain characteristics.

U.S. Pat. No. 5,732,162, granted Mar. 24, 1998, to Curry, for Two dimensional linearity and registration error correction in a hyperacuity primer, describes a system wherein mechanical misregistrations are compensated by manipulating stored data in a register.

U.S. Pat. No. 5,737,003, granted Apr. 7, 1998, to Moe et al., for Systems for registration of color separation images on a photoconductor belt, describes use of a laser scanner to form a latent image on a photoconductive belt, and to detect the position of the edge of the belt. The belt is then controlled to reduce the deviation of the belt from its path the reference also includes a method for controlling the laser, and therefore the formation of the image, based upon the position of the belt.

U.S. Pat. No. 5,760,815, granted Jun. 2, 1998, to Genovese, for Fiber optic registration mark detection system for a color reproduction device, describes storing predetermined patterns to detect color registration in an imaging circuitry.

U.S. Pat. No 5,764,388, granted Jun. 9, 1988, to Ueda et al, for Method and device for converting color signal, describes a method for detecting and removing color fringing produced by a color ink jet printer. The method converts CMY signals into chromatic and achromatic components The achromatic component is obtained by under color removal k=min (c, m, y), and the chromatic component is obtained by c1=c−k, m1=m−k, etc. If the maximum of chromatic component is smaller than a pre-determined threshold, the color component is set to (c2, m2, y2), which is smaller than (c1, m1, y1). This results in a more gray output. If, on the other hand, the maximum of chromatic component is greater than a predetermined threshold, the chromatic signals weighting is left unchanged.

U.S. Pat. No. 5,774,156, granted Jun. 30, 1998, to Guerin, for Image self-registration for color printers, describes another mechanical registration technique. The system uses several stations, one for each color of toner. A latent image is formed by the individual scanners at the stations and includes a registration area. The registration area is then aligned prior to the application of the toner. The registration area is then recharged to avoid having the registration marks attract any toner. This is repeated at each station to ensure proper positioning of the image before the latent image for the next color is formed.

U.S. Pat. No. 5,852,461, granted Dec. 22, 1998, to Noguchi, for Image formation system and color misregistration correction system, describes a system wherein deviation of a scanning device from its optimal position is detected and used to align image components.

U.S. Pat. No. 5,907,414, granted May 25, 1999, to Hiratuka, for Color image processing Apparatus, describes a method for correcting misregistration wherein a standard color signal is selected and the brightness level of other color signals are computed from the relation between the brightness of current pixel and neighbors based on this color signal.

U.S. Pat. No. 5,907,414, granted May 25, 1999, to Hiratuka, for Color image processing apparatus, describes a method of correcting misregistration where a standard color signal (G) is selected and the brightness level of other nonstandard (R, B) color signals are computed from the relation between the brightness of current pixel and neighboring pixel based on this color's current signal. Color misregistration detection is based on edge detection e.g. abs (R[−1]−R[1]>80), flatness detection, for identifying text and background. An assumption is made that a pixel inside a letter image and in the background image is constant e.g. abs (R[−2]−R[−3])<20, and that level detection, R[−2]<R[0]<R[2]∥R[−2]<R[0]<R[2] All of the detector's threshold parameters are predetermined based on subjective and experimental data.

### SUMMARY OF THE INVENTION

A method for correcting misregistration of scanned thin line character components includes detecting a misregistered pixel; determining whether the misregistered pixel is part of a character; applying a three-dimensional color vector determinant to the misregistered pixel; and reducing the chrominance component of the misregistered pixel to provide a corrected pixel.

An object of the invention to introduce a technique which automatically identifies and corrects color misregistration problems for alphabet characters having thin lines.

Another object of the invention is to provide a method of image analysis using three-dimensional color vector determinant to identify or classified features in an image.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 depicts the scanned result of image without the presence of color misregistration causing color fringing around text.

FIG. 2 depicts the scanned result of image with the presence of color misregistration causing color fringing around text.

FIG. 3 is a flowchart of one embodiment of a method for detecting and correcting color misregistration in Kanji in accordance with the invention.

FIG. 4 depicts misregistration of one pixel in the red channel.

FIG. 5 depicts an image scanned without the method of the invention.

FIG. 6 depicts the scanned image of FIG. 5 corrected by the method of the invention.

FIG. 7 depicts the scanned image of FIG. 5 corrected by a modified form of the method of the invention.

FIG. 8 depicts an image scanned without the method of the invention.

FIG. 9 depicts the image of FIG. 8 corrected by the method of the invention

### DETAILED DESCRIPTION OF THE PREFERRED EMBODIMENT

As previously noted, the known prior art does not include techniques specifically to solve color misregistration problems for Kanji or Chinese characters. Perhaps, this is because such characters contain many very thin strokes, which may appear at many different angles Kanji characters frequently contain thin line strokes that are, once scanned, only one or two pixels wide. These pixels may occur in the middle or at the end of a stroke in 45°, 0 °, or 90° The difficulty in scanning Kanji characters is that the characters include lines ranging between very broad to very thin. The problem of color misregistration is exacerbated by the very thin portions of these characters. Other alphabets having a combination of very thick and thin lines include Arabic, Hebrew, Greek, and Cryllic, and share this problem. At the location of a transition to a very thin stroke, the scanned data has insufficient information from the surrounding areas to correct any damaged pixel in the scanned character. Any attempt at correction through interpolation or smoothing will likely make the situation worse.

The technique of the invention is a method of image analysis using three-dimensional color determinant mathematics. Through the use of the method described herein, the color misregistration problem in Kanji, and similar alphabets, may now be detected and resolved automatically, as it will be apparent after a reading of the following description Although the techniques described herein may be applicable to a number of alphabets, the description which follows will focus on resolution of scanning problems in the Kanji alphabet. While it is an additional object of present invention to disclose a new method of image analysis using three-dimensional color vector determinant to identify or classified features in an image, and while 3D color vector determinant method may easily be applied to other fields and applications, such as segmentation, compression, and pattern recognition, the applications of 3D determinant mathematics for the analysis of image content into these and other fields are beyond the scope of the present disclosure.

This invention, using three-dimensional color vector determinant mathematics, enables a rapid detection of misregistration in Kanji. The total processing cost for text and misregistration detection is only two multiplications, three additions, and one comparison, making this invention very competitive both in speed and cost.

The techniques described in U.S. Pat. No. 5,907,414, or the one proposed in the above-identified related application, are state of the art interpolation and information recovery techniques, which work well for Roman characters, but which actually may degrade image quality when applied to scanned thin line portions of a Kanji character.

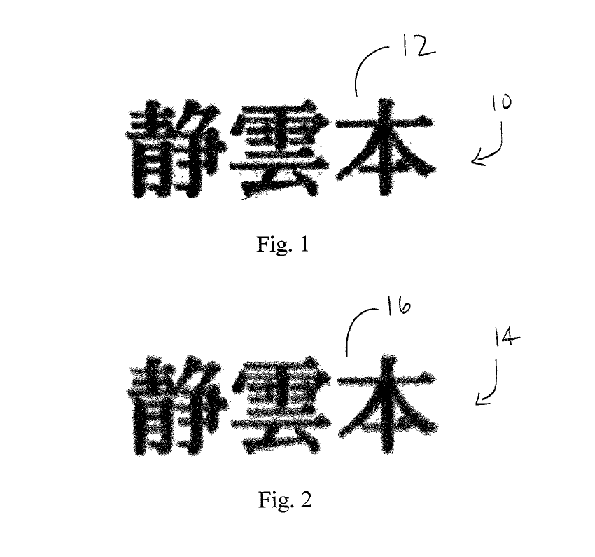

FIGS. 1 and 2 depict scanned images which are uncorrected and corrected by the three-dimensional color vector determinant technique described here, respectively, which technique performs color correction through vector manipulations in RGB color space for the detection of color misregistration in Kanji characters. FIG. 1 depicts the scanned result 10 of an image processed without color misregistration. The image has sharp edges and the character components are uniformly black. The background 12 is uniformly grey. FIG. 2 depicts the scanned result 14 of an image processed with color misregistration. The image has fuzzy edges and the character components are surrounded by a color fringe. The background 16 has a magenta cast when viewed in color.

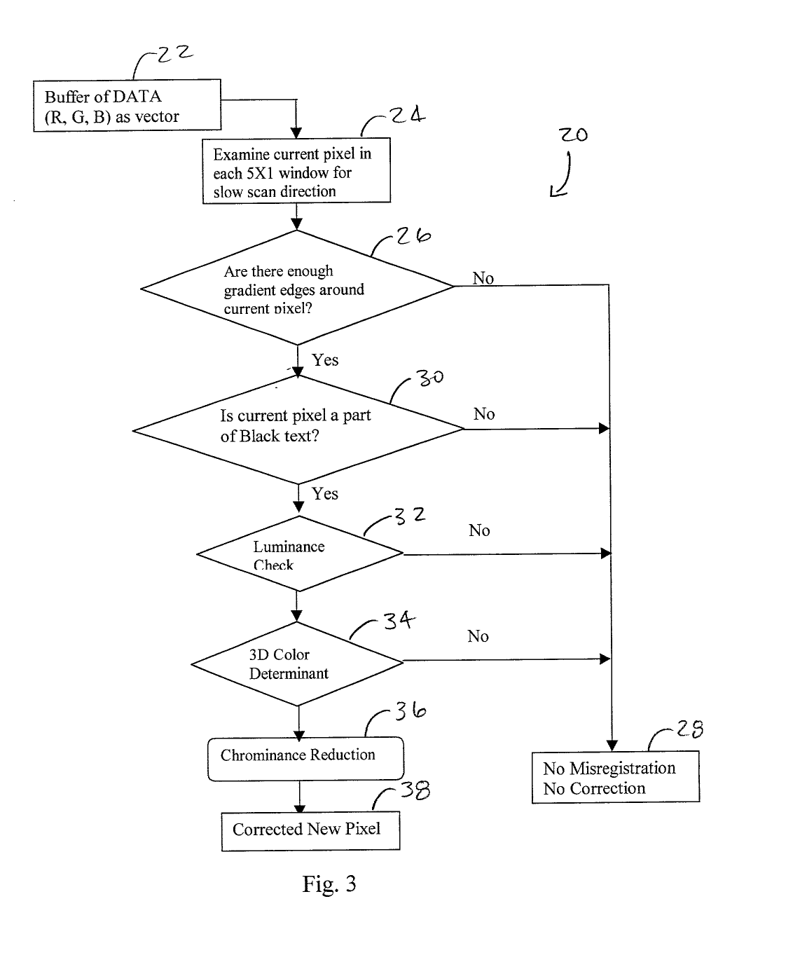

FIG. 3 illustrates a flowchart for an example of automatic color misregistration correction used in the present invention's embodiment, generally at 20. Certain edge and misregistration conditions must be satisfied before a pixel may undergo classification for 3D determinant analysis for color enhancement. A two-pass technique is performed to identify all the pixels that are in an edge and possibly have color misregistration from an input image in both the X direction and Y direction.

In the following example, input data is acquired from an input-capturing device such as a CCD The RGB signals are then digitized and converted into eight bits per channel and stored into a buffer, block 22, such as FIFO (first in first out) Then for each captured pixel data, a line of RGB values are transferred into RGB vector space for processing in a color misregistration detection circuit, apparatus, or algorithm. For clarity, the mathematical notations for color vectors used herein are defined as follows.

For any two color pixels, A and B, in the RGB color space, two color vectors are defined as

PA=(Ra,Ga,Ba) and PB=(Rb,Gb,Bb) (1)

then, the gradient between pixel A and pixel B is defined to be

dab=(dRAB, dGAB, dBAB)=(Ra−Rb, Ga−Gb, Ba−Bb) (2)

The magnitude of this gradient is defined as DAB, i.e., DAB=magnitude (dab)

Before the three-dimensional color vector determinant method is executed certain detection criteria must first be satisfied to detect a misregistered pixel. One may first find an edge pixel position and confirm that this is a text region. This is an optional step, and the purpose is solely to enhance the speed of the algorithm so that pixels that are not in or near an edge position may quickly be eliminated without further processing. Once the edge pixel position is determined, analysis continues to detect color misregistration and to provide pixel enhancement, otherwise; the processing terminates and the pixel is classified as properly registered, i.e., not misregistered.

Edge Detection

The color misregistration problem is most visually disturbing around high gradient edge areas, such as found in text and drawings. Therefore, the first step of the present vector based method is to eliminate any pixel area not having enough gradient by using a special edge detector. An edge detector, such as a Sobel filter or a differential filter, may be used, and will probably produce good results. However, a gradient edge detector is provided as a part of the invention herein, which will provide superior detection for the type of gradient patterns commonly found in misregistration cases of the alphabets characters in question. One object of the edge detector design is to be able to identify thin and narrow characters commonly found in Kanji. In these locations, there is usually not enough information in the image to determine a color misregistration error. Hence, the need for processing using the 3D color determinant mathematics of the invention, which will be described later herein, on these pixels.

A small window, which encompasses a current pixel and neighboring pixels is used for this edge detector. The size of the window used in the detection algorithm is five pixels in the sub-scanning, or slow-scan, direction and one pixel in the main scanning direction, block 24 This means that the technique described herein is applied only in the sub-scan direction. It is important to note that both the size and direction may be further adjusted for more optimum results in different applications. The sequence below depicts the image filter kernel used in present embodiment for edge detection:

−2 −1 0 1 2 (3)

If the result of edge detection is smaller than a predetermined threshold, the pixel in question is not located at the edge of a character, block 26 Consequently, the pixel is classified as “no color misregistration,” and there is no need for correction or further processing with the 3D color determinant analysis and classification, block 28. The algorithm terminates at this point

Text Detection

After an edge is detected, using the above kernel (Eq. 3), the pixel in questions need to be identified as to whether it is part of an alphabet character, block 30. Assume, for the moment, that the text in question is displayed in black. There are many different techniques in prior art to detect such text. A simple two step process to determine whether the pixel is part of a character, based on gradient and luminance, is disclosed in the above-identified related application, which is incorporated herein by reference.

Gradient Check

A pixel which is located at the edge of a character will have a gradient between the foreground and background which is higher than the gradient of the current pixel to foreground and background, or:

D(a,b)>D(a,0) AND D(a,b)>D(b,0) (4)

Where a, b is the background and foreground respectively and 0 is the current pixel.

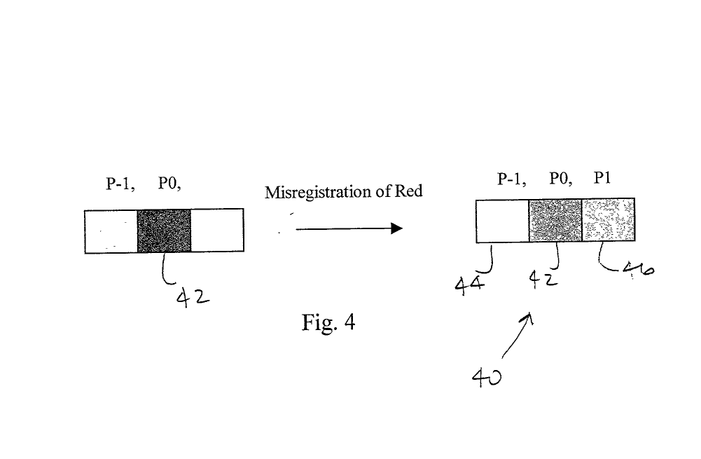

In extreme thin line Kanji situation, some strokes are so small that the foreground and the background are blurred due to misregistration, and a pixel in such a region cannot be detected or classified. In this case, a and b in Eq. (4) correspond to color fringing pixels in the left and to the right, as illustrated in FIG. 4, generally at 40.

Luminance Check

A simple approximation is used to convert foreground, background, and current pixel to a luminance value, block 22, that is:

L(a)=0.5G(a)+0.3R(a)+0.2B(a) (5)

Other values and techniques for the luminance approximation may also be used. Different coefficients for luminance transformation may be used to produce better results and device customization. For a pixel to be located at the edge of a character, the luminance of the current pixel must be in between the background luminance and the foreground luminance:

L (background)<L (current pixel)<L (foreground)—or—

L (background)>L (current pixel)>L (foreground) (6)

Three-dimensional Color Vector Determinant—Block 34

Color misregistration is caused by misalignment of a color channel e.g., red. If the red channel is misregistered, then color fringing of red and cyan in the left and to the right occurs. In the same way, misregistration of the green channel will cause color fringing of green and magenta. Moreover, for blue, color fringing of blue and yellow occurs surrounding the text.

For simplicity, the following depicts the calculation for red channel misregistration. Other channels may be extended in a similar fashion. FIG. 4 illustrates color misregistration of one misregistered pixel in the red channel 42 to the right. As shown in FIG. 4, shifting the red channel causes color fringing of red 44 and cyan 46.

Null Vector Color Space

If maximum color misregistration is assumed, the color-fringing vector Pa and Pb may be represented by Eqs. (7) and (8):

Ideal misregistration Pa=(Ra, Ga, Ba)=(1, 0, 0) (7)

Ideal misregistration Pb=(Rb, Gb, Bb) =(0, 1, 1) (8)

Eqs. (7) and (8) span a two-dimensional color space where, if the image contains red color misregistration, the color vector Pa and the color vector Pb must be in the two-dimensional vector space spanned by the vector in Eq (7) and the vector in Eq. (8). In other words, if there is color misregistration, color-fringing vector Pa and color fringing vector Pb may be described as linear combination of the vectors in Eqs (7) and (8). If no red color channel misregistration is present, then the color vector Pa and color vector Pb must be in the null space spanned by the vector in Eq (7) and the vector in Eq. (8). The notation for the null space of red color misregistration is Nrm, and is calculated by:

Nrm=(0, −1, 1) (9)

Following the notation of FIG. 4, where Pa=P−1, and Pb=P1, to calculate and estimate the amount of red color misregistration, the control vector volume span by the three basis vectors Nrm, P−1, and P1 must be determined. A three-dimensional matrix containing these three vectors is illustrated by:

$$[ \begin{matrix}Nrm \\ P + 1 \\ P - 1\end{matrix} ] = [ \begin{matrix}0 & - 1 & 1 \\ R1 & G1 & B1 \\ R - 1 & G - 1 & B - 1\end{matrix} ] \qquad ( 10 )$$

Ideally, if no color misregistration is present, then the matrix in Eq (10) has rank one, and all three vectors in the matrix are linearly dependent. On the other hand, if color misregistration is detected, the control volume spanned by the three vectors is maximum, and the three vectors will form a basis vector which spans the three-dimensional color vector space. In reality, however, the control volume is usually not zero or maximum. The magnitude of the control volume size spanned by the three vectors provides only an estimate of the amount of red misregistration present in the image, by calculating the determinant of the matrix described of Eq. (10) If the determinant is zero, then no color misregistration is present. Otherwise, the amount of color misregistration will be the size of the absolute value of the determinant of matrix (10).

To solve the matrix for its determinant in Eq. (10) a Laplace expansion may be used. For convenience, the solution of the determinant is shown in Eq. (11):

Determinant (matrix (Nrm, P1, P−1))=R1(G1+B−1)−R−1(B1+G1) (11)

Eq. (11) represents the formula for calculating the amount of red color misregistration present in that pixel.

Similar, color misregistration of green channel and blue channel may be calculated by

Green channel: G1(R−1+B−1)−G−1(B1+R1) (12)

Blue channel: B1(R−1+G−1)−B−1(G1+R1) (13)

Using the above formulae, red color misregistration detection is determined by:

Fabs (R1(G−1+B−1)−R−1(B1+G1) ) <T (14)

Where T is a threshold determined based on experimentation and device customization. The absolute value is used for comparison because only the volume spanned in the 3D vector space is of concern, and volume is always positive.

Green and blue channel misregistration is similarly determined, although each has different perception by the HVS than red. In one embodiment, different weightings are applied to Eqs (12) and (13) to reflect HVS perception based on psychophysic evaluation and device customization. Details on weighting function to reflect HVS perception is, however, beyond the scope of this invention.

Fuzzy Chrominance Reduction

Once a color misregistration error in a thin line situation is detected, a chrominance reduction step, block 36, is performed. There are many known chrominance reduction transformations. One example of chrominance reduction includes using a linear projection based on Eq (5) above Specific chrominance transformation mapping technique is beyond the scope of the present disclosure. The amount of chrominance reduction used herein is based on the 3D color vector determinant calculation as described in Eqs (11), (12), and (13) above This provides a fuzzy relationship in the chrominance reduction. Details of fuzzy functions that may be used with above equations are also beyond the scope of the invention, but are well known to those of ordinary skill in the art.

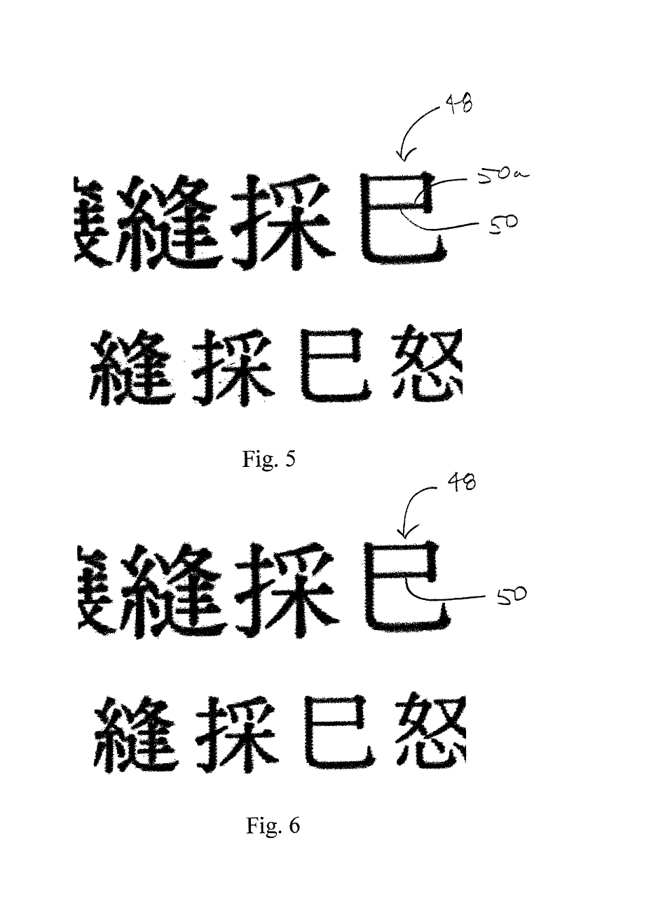

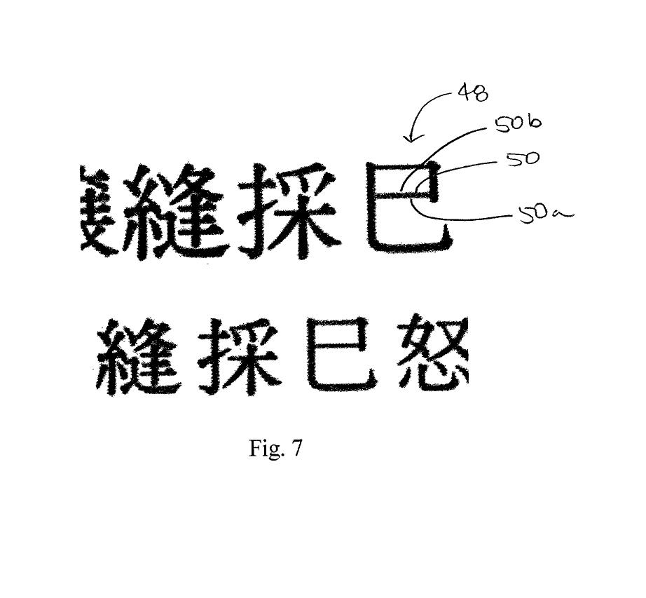

Referring now to FIG. 5, character 48 includes a cross member 50, having a cyan fringe area 50a located above the upper margin thereon. As depicted in FIG. 6, character 48, after processing according to the method of the invention, no longer has the fringe area, and presents a sharper appearance. As shown in FIG. 7, character 48 has a sharper appearance than in FIG. 5, however, a very thin magenta fringe 50a is present below line 50 and a very thin cyan fringe 50b is present above line 50.

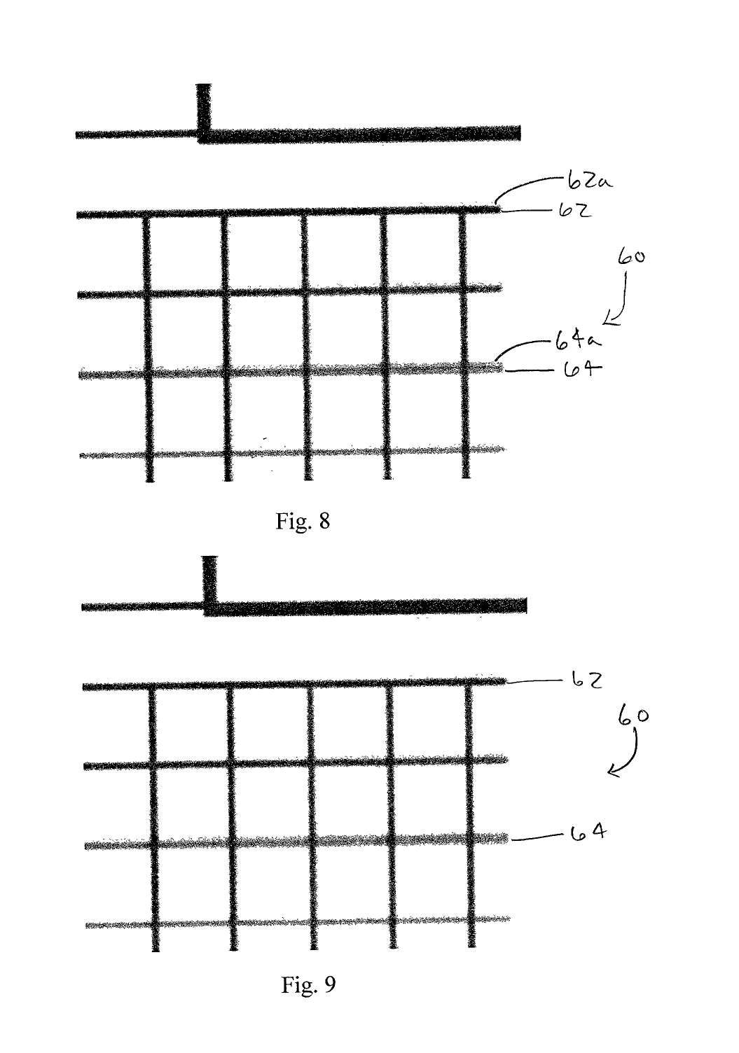

FIG. 8 depicts a grid 60 having horizontal lines 62 and 64 therein. Both lines 62, 64 have a magenta fringe 62a, 64a, located above the respective line, which substantially disappear, as shown in FIG. 9, after application of the method of the invention.

It should be noted that the above vector calculations are not normalized. If vector calculations are normalized, it will have the same effect as removing luminance. On the other hand, HVS perception is known to have a proportional relationship to luminance. Normalizing the color vectors might not describe the behavior of human vision. The exact human visual model and transformation that may be used in the above equations to produce the best result is determined by empirical methods for particular scanning mechanisms and procedures.

Preferred embodiment for implementing the invention includes an imaging apparatus for character detection and correction, color misregistration detection and removal, segmentation, and compression. Such an apparatus may be used in digital video, such as in a display device, or in a digital output device, such as a color copier or color printer. The invention is most likely implemented in software. The software algorithms may be incorporated into image or graphic application software, color printer, color copier, and output device drivers. The algorithms for automatic reduction of color fringing may also be implemented in an ASIC, FPGA, or in a digital signal processor (DSP), using micro-codes.

Although the fundamental core vector-based color misregistration correction described herein uses RGB input, this may be extended for other color spaces, such as CMY, CMYK, and other luminance/chrominance based color spaces, such as LAB, LCH, HLS, etc.

It should be noted further that the specific technique for three-dimensional color vector determinant may be easily modified and implemented by one of ordinary skill in the art, without departing from the scope of the invention as defined in the appended claims.

Thus, a method of three dimensional color vector determinant for automatic character detection and enhancement has been disclosed. It will be appreciated that further variations and modifications thereof may be made within the scope of the invention as defined in the appended claims.

We claim:

1. A method for correcting misregistration of scanned thin line character components, comprising:
detecting a misregistered pixel;
determining whether the misregistered pixel is part of a character,
applying a three-dimensional color vector determinant to the misregistered pixel; and
reducing the chrominance component of the misregistered pixel to provide a corrected pixel.

2. The method of claim 1 wherein said detecting include identifying a pixel as being at an edge of an image portion.

3. The method of claim 2 wherein said identifying includes identifying a pixel as being at an edge of an image portion using a gradient edge detector, including selecting an image kernel filter, having integer values GTE −2 and LTE +2, including zero, setting a predetermined threshold, comparing the image filter kernel to the predetermined threshold, and classifying the pixel as a misregistered pixel IFF the image filter kernel is greater than the predetermined threshold

4. The method of claim 1 wherein said determining includes checking the gradient and checking the luminance of a pixel.

5. The method of claim 1 wherein said reducing includes reducing the chrominance component of the misregistered pixel to provide a corrected pixel with a fuzzy chrominance reduction function.

6. The method of claim 1 which further includes locating an edge pixel position and classifying the edge position pixel as a text region.

7. A method for correcting misregistration of scanned thin line character components, comprising:
detecting a misregistered pixel, including identifying a pixel as being at an edge of an image portion,
determining whether the misregistered pixel is part of a character, including checking the gradient and checking the luminance of a pixel;
applying a three-dimensional color vector determinant to the misregistered pixel, and
reducing the chrominance component of the misregistered pixel to provide a corrected pixel.

8. The method of claim 7 wherein said identifying includes identifying a pixel as being at an edge of an image portion using a gradient edge detector, including selecting an image kernel filter, having integer values GTE −2 and LTE +2, including zero, setting a predetermined threshold, comparing the image filter kernel to the predetermined threshold, and classifying the pixel as a misregistered pixel IFF the image filter kernel is greater than the predetermined threshold

9. The method of claim 7 wherein said reducing, includes reducing the chrominance component of the misregistered pixel to provide a corrected pixel with a fuzzy chrominance reduction function.

10. The method of claim 7 which further includes locating an edge pixel position and classifying the edge position pixel as a text region.

11. A method for correcting misregistration of scanned thin line character components, comprising
detecting a misregistered pixel, including identifying a pixel as being at an edge of an image portion, wherein said identifying includes identifying a pixel as being at an edge of an image portion using a gradient edge detector, including selecting an image kernel filter, having integer values GTE −2 and LTE +2, including zero, setting a predetermined threshold, comparing the image filter kernel to the predetermined threshold, and classifying the pixel as a misregistered pixel IFF the image filter kernel is greater than the predetermined threshold;
determining whether the misregistered pixel is part of a character, including checking the gradient and checking the luminance of a pixel;
applying a three-dimensional color vector determinant to the misregistered pixel; and
reducing the chrominance component of the misregistered pixel to provide a corrected pixel.

12. The method of claim 11 wherein said reducing includes reducing the chrominance component of the misregistered pixel to provide a corrected pixel with a fuzzy chrominance reduction function.

13. The method of claim 11 which further includes locating an edge pixel position and classifying the edge position pixel as a text region
